(19) United States
(12) Patent Application Publication
(10) Pub. No.: US 2016/0188495 A1
(43) Pub. Date: Jun. 30, 2016

(54) EVENT TRIGGERED ERASURE FOR DATA SECURITY

(71) Applicant: INTEL CORPORATION, Santa Clara, CA (US)

(72) Inventors: Helia NAEIMI, Santa Clara, CA (US); Shigeki TOMISHIMA, Portland, OR (US); Shih-Lien L. LU, Portland, OR (US)

(21) Appl. No.: 14/583,518

(22) Filed: Dec. 26, 2014

(51) Int. Cl. G06F 12/14; G06F 12/02; G11C 16/34; G11C 14/00; G11C 11/16; G11C 16/10

(52) U.S. Cl. CPC G06F 12/1425; G11C 11/161; G11C 16/107; G11C 16/105; G11C 16/3486; G11C 14/0081; G06F 12/0246; G06F 2212/7205; G06F 2212/7209; G06F 2212/1052

(57) ABSTRACT

One aspect of the present description provides for automatically erasing at least a portion of a memory such as a nonvolatile memory, for example, of a device in response to a detected event such as a power shutdown or power-up process, for example. In one embodiment, an on-board erasure assistance device such as an electro-magnet, for example, facilitates sensitive data erasure. In accordance with another aspect of the present description, a satisfactory level of sensitive data erasure may be achieved by resetting a portion of the bits of the sensitive data, instead of resetting all the bits of sensitive data. In one embodiment, the bits which are reset to erase sensitive data may be randomly distributed over a subarray. Other aspects are described herein.

### TECHNICAL FIELD

Certain embodiments of the present invention relate generally to nonvolatile memory.

### BACKGROUND

Spin Transfer Torque Random Access Memory (STTRAM) is a type of magnetoresistive Random Access Memory (MRAM) which is nonvolatile and is typically used for memory circuits, such as, cache, memory, secondary storage, and other memory applications. STTRAM memory may often be operated at reduced power levels and may be less expensive as compared to other memory types.

Further, as a nonvolatile memory, data stored in STTRAM memory is retained. Accordingly, the STTRAM retains data during stand by and even power down conditions. As such STTRAM is very attractive from a performance and power point of view. However, such data retention may not be appropriate for storing sensitive data, particularly in portable devices which may be stolen or otherwise more readily accessed by unauthorized users.

One approach for protecting sensitive data has been to program the operating system of the device to place sensitive data in volatile memory. Accordingly, once the device enters the power down condition, removal of power from the volatile memory typically destroys the data in the volatile memory including any sensitive data placed in the volatile memory.

Another approach has been to provide for remote control of devices such as cellular telephones, for example, which may be lost or otherwise no longer in the possession of the owner. Such remote control features may permit the rightful owner of the cellular telephone to remotely erase data stored in the memory of the telephone.

### BRIEF DESCRIPTION OF THE DRAWINGS

Embodiments of the present disclosure are illustrated by way of example, and not by way of limitation, in the figures of the accompanying drawings in which like reference numerals refer to similar elements.

FIG. 1A depicts a high-level block diagram illustrating selected aspects of a system, in accordance with an embodiment of the present disclosure.

FIG. 1B depicts a basic architecture of an STTRAM memory in accordance with an embodiment of the present disclosure.

FIGS. 1C-1F depict various polarizations of ferromagnetic layers of a bitcell of the STTRAM memory of FIG. 1B.

FIGS. 2A-2B depict a schematic of a typical one-transistor-one-resistor (1T1R) device showing the bit-line (BL), word-line (WL) and source line (SL).

FIG. 3 is a chart depicting one example of typical read and write voltages for the one-transistor-one-resistor (1T1R) device of FIGS. 2A-2B.

FIG. 4A is a schematic representation of directing a magnetic field for magnetic field-assisted sensitive data erasure through ferromagnetic layers of a subarray of bitcells of the STTRAM memory of FIG. 1B in accordance with an embodiment of the present disclosure. In this figure arrows represent a polarization of the “free layers” as explained below.

FIG. 4B is a schematic representation of a coil disposed over a subarray of bitcells of the STTRAM memory of FIG. 1B for directing a magnetic field for magnetic field-assisted sensitive data erasure through the subarray of bitcells in accordance with an embodiment of the present disclosure.

FIG. 5A is a schematic representation of an alternative embodiment of directing a magnetic field for magnetic field-assisted sensitive data erasure through ferromagnetic layers of a subarray of bitcells of the STTRAM memory of FIG. 1B in accordance with an embodiment of the present disclosure. Again, in this figure arrows represent a polarization of the “free layers” as explained below.

FIG. 5B is a schematic representation of a cross-sectional view of the subarray of the magnetic field and free ferromagnetic layers of FIG. 5A.

FIG. 5C is a schematic representation of an alternative embodiment of a coil disposed over a subarray of bitcells of the STTRAM memory of FIG. 1B for directing a magnetic field for magnetic field-assisted sensitive data erasure through the subarray of bitcells in accordance with an embodiment of the present disclosure.

FIG. 5D is a schematic representation of an alternative embodiment of the coil of FIG. 5C.

FIG. 6 depicts an example of operations for on-board device-assisted sensitive data erasure in a memory in accordance with an embodiment of the present disclosure. FIG. 7 depicts an example of operations for magnetic field-assisted sensitive data erasure in a memory in accordance with an embodiment of the present disclosure.

FIG. 8 depicts another example of operations for magnetic field-assisted sensitive data erasure in a memory in accordance with an embodiment of the present disclosure.

FIG. 9 is a timing diagram depicting an example of control signals generated in association with a power up event for magnetic field-assisted sensitive data erasure in a memory in accordance with an embodiment of the present disclosure.

FIG. 10 depicts an example of operations for random selection of bitcells for magnetic field-assisted sensitive data erasure in a memory in accordance with an embodiment of the present disclosure.

### DESCRIPTION OF EMBODIMENTS

In the description that follows, like components have been given the same reference numerals, regardless of whether they are shown in different embodiments. To illustrate an embodiment(s) of the present disclosure in a clear and concise manner, the drawings may not necessarily be to scale and certain features may be shown in somewhat schematic form. Features that are described and/or illustrated with respect to one embodiment may be used in the same way or in a similar way in one or more other embodiments and/or in combination with or instead of the features of the other embodiments.

One aspect of the present description provides for automatically erasing at least a portion of a nonvolatile memory such as an STTRAM array, for example, of a device in response to a detected event such as a power shutdown or power-up process, for example of the device. As used herein, the term “erase” refers to changing or resetting bits stored in memory to eliminate or increase the difficulty of unauthorized recovery of sensitive data stored in the memory. Thus, bits of sensitive data may be erased by setting bits to a logical zero or in some embodiments, by setting bits to a logical one. In other embodiments, bits of sensitive data may be erased by randomly flipping states of bits of the sensitive data from their present state to the opposite state.

It is recognized herein that it may be appropriate to erase sensitive data stored in nonvolatile memory of a device in response to certain events to prevent unauthorized access to the sensitive data which may have been stored in the device. It is further recognized that such sensitive data erasure may be triggered by events in addition to or instead of a power shutdown or power-up process, depending upon the particular application.

It is appreciated that preserving the security of sensitive information stored in various devices is of growing concern as the number of devices containing sensitive information proliferates. Sensitive information may include passwords, account numbers, or other information of a business, financial or personal nature. In addition, devices containing such information are becoming increasingly small and portable and therefore more vulnerable to being stolen. Sensitive information stored in a memory of a device in the possession of an unauthorized person may be extracted and used or otherwise disseminated by the unauthorized person.

In one embodiment, such sensitive data erasure is facilitated by an on-board erasure assistance device such as an electro-magnet, for example, which is carried on the device and positioned adjacent to a memory such as STTRAM array. The erasure assistance device may reduce one or both of the write time and the write current for resetting bits of the STTRAM. In this manner, it is believed that erasure of sensitive data may be achieved more quickly and at reduced power levels to provide improved data security.

It is recognized herein that STTRAM write energy is typically relatively high as compared to other types of memory. As a result, in applications which may have a limited amount of write current available over a limited period of time such as when a device is powering down or powering up, it may be difficult to reset a large number of bits within that time period. In addition, it is recognized that STTRAM write time is also typically relatively long as compared to other types of memory. As such, resetting a large number of bits in an STTRAM array may take a correspondingly long period of time to complete.

In accordance with one aspect of the present description, an on-board erasure assistance device is activated when erasing sensitive data, to reduce one or both of write current and write time to facilitate bit erasure of sensitive data in a memory such as an STTRAM, for example. In one embodiment, the erasure assistance device is a source of noise which facilitates resetting bits of sensitive data to erase those bits. For example, the erasure assistance device of one embodiment can provide a magnetic field directed through a subarray of bitcells of the STTRAM containing sensitive data. As a result, the write current and the write time to reset bitcells of the subarray may be reduced in the presence of the applied magnetic field of the erasure assistance device. In one embodiment, it is believed that the write time and write energy may decrease as a function of the square of the magnitude of the applied magnetic field of the on-board erasure assistance device.

In accordance with another aspect of the present description, it is recognized that a satisfactory level of sensitive data erasure may be achieved in many applications by resetting a portion of the bits of the sensitive data, instead of resetting all the bits of sensitive data. By resetting a portion of the bits of the sensitive data, unauthorized recovery of the sensitive data may be made sufficiently impractical as to adequately protect the sensitive data without resetting all the bits of the sensitive data. As a result, the amount of write current and the amount of time utilized to achieve the erasure of the portion of the bits containing the sensitive data may be reduced as compared to the amount of write current and the amount of time utilized to achieve the erasure of all of the bits containing the sensitive data.

The percentage of bits of the sensitive data which is reset to achieve a desired level of security may vary, depending upon the particular application. For example, in some applications, the percentage of bits which are reset may be in a range of from 40 to 60 percent of the total number of bits of the sensitive data, for example. In other applications it may be appropriate to erase at least 50% of the bits to render the remaining bits as effectively random bits. However, in still other applications, it may be appropriate to erase more bits, such as approximately 80% of the bits. It is appreciated that the level of appropriate erasure may depend on the sensitivity of the data and the security algorithm if any that was used to encrypt date. For example in a Rivest-Shamir-Adleman (RSA) cryptosystem, the most sensitive data may be the private RSA key. In view of algorithms that can reconstruct a key with as little as 15% of the bits, it may be appropriate to erase at least 85% of the bits of a key. In other applications, it may be appropriate to erase all bits of the sensitive data.

In one embodiment in which the sensitive data is stored in a subarray of the memory, the portion of bits which are reset to erase sensitive data may be randomly distributed over the subarray. Such a random distribution of reset bits of sensitive data is believed to enhance prevention of unauthorized recovery of the sensitive data. It is recognized that random distribution of reset bits of sensitive data may be achieved in a variety of techniques, depending upon the particular application.

For example, it is recognized that physical characteristics of individual bitcells of an array of bitcells in a memory may vary from bitcell to bitcell as a result of variations encountered in typical fabrication processes. One such physical characteristic which may randomly vary from bitcell to bitcell is the level of write current at which a particular bitcell may be reset from one state to another. Thus, a percentage of the bitcells of a subarray may be reset with a relatively weak write current. Such bitcells referred to herein as “weak bitcells” may also be reset relatively quickly as compared to other bitcells of the array. As a consequence, “weak bit” bitcells which may be reset relatively quickly with a relatively weak write current may be randomly distributed over a subarray. By applying the relatively weak write current to the subarray over a relatively short period of time, the weak bit bitcells may be reset. Conversely, those “strong bit” bitcells which may be reset upon application of a relatively strong write current over a relatively long period of time may remain unchanged in the presence of the weak write current. However, the resetting of the randomly distributed weak bit bitcells may be sufficient to render unauthorized recovery of the sensitive data of the subarray as a whole sufficiently impractical notwithstanding that the bits of the strong bitcells may remain unchanged. In this manner, write current and write time for sensitive data erasure may be correspondingly reduced to a level lower than that utilized to ensure resetting of all bitcells including strong bit bitcells.

In another aspect of the present description, random distribution of reset bits to protect against unauthorized recovery of sensitive data may be achieved by an on-board randomization circuit. In response to detection of an event such as a power shutdown or power-up process, the randomization circuit may randomly select bits of the sensitive data to be reset. It is appreciated that in some embodiments, erasure of bits of sensitive data may occur automatically in response to detection of a security related event. In other embodiments, sensitive data erasure may be triggered manually by the authorized user using an on-board erasure assistance device.

In one embodiment, an on-board erasure assistance device such as an electro-magnet, for example, which is carried on the device and positioned adjacent to the memory array, provides magnetic field-assisted sensitive data erasure for an MRAM memory such as an STT memory is described. STT is an effect in which the orientation of a magnetic layer in a magnetic tunnel junction (MTJ) device can be modified using a spin-polarized current. In STT-based MTJs, device resistance can be either low or high, depending on the relative angular difference between the directions of magnetic polarization on both sides of the tunnel junction.

In one embodiment, a magnetic field is directed through a ferromagnetic layer of an MTJ device of bitcells of a subarray of bitcells to facilitate a state change of each MTJ from a first state to a second state for purposes of erasing bits of sensitive data. In one embodiment, the first state is one in which the ferromagnetic layers of the each MTJ have a parallel magnetic orientation and exhibit low resistance. Conversely, the second state is one in which the ferromagnetic layers of each MTJ have an anti-parallel magnetic orientation and exhibit high resistance. It is believed that the magnetic assistance provided by the magnetic field directed through the MTJ, can facilitate the change in state from the first (parallel orientation, low resistance) state representing a logical one, for example, to the second (anti-parallel, high resistance) state representing a logical zero, for example. Similarly, it is believed that the magnetic assistance provided by the magnetic field directed through the MTJ, can facilitate the change in state from the second (anti-parallel, high resistance) state to the first (parallel orientation, low resistance) state. Thus, magnetic field-assisted sensitive data erasure may be achieved by resetting selected bits of sensitive data to a logical one, or to a logical zero, depending upon the particular application. As explained in greater detail below, it is believed that such magnetic assistance can reduce write times and hence erasure times at least a portion of the STT memory in some embodiments.

It is appreciated that sensitive data erasure techniques as described herein may be applied to memory devices other than nonvolatile memory and may be applied to nonvolatile memory devices other than STTRAM devices. It is further appreciated that the magnetic field bit erasure assistance techniques as described herein may be applied to MRAM devices other than STT MRAM devices such as giant magnetoresistance (GMR) MRAM, toggle MRAM and other MRAM devices. Such memory elements in accordance with embodiments described herein can be used either in stand-alone memory circuits or logic arrays, or can be embedded in microprocessors and/or digital signal processors (DSPs). Additionally, it is noted that although systems and processes are described herein primarily with reference to microprocessor based systems in the illustrative examples, it will be appreciated that in view of the disclosure herein, certain aspects, architectures, and principles of the disclosure are equally applicable to other types of device memory and logic devices.

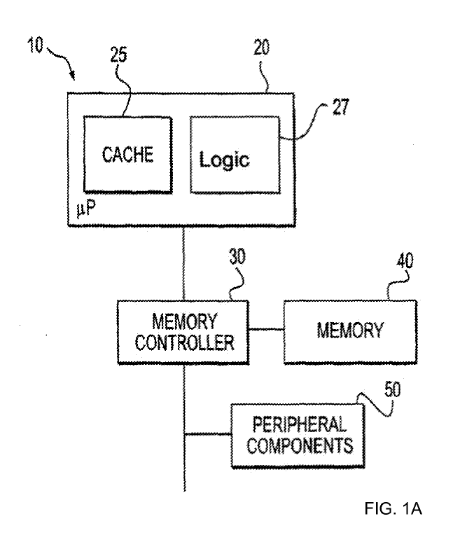

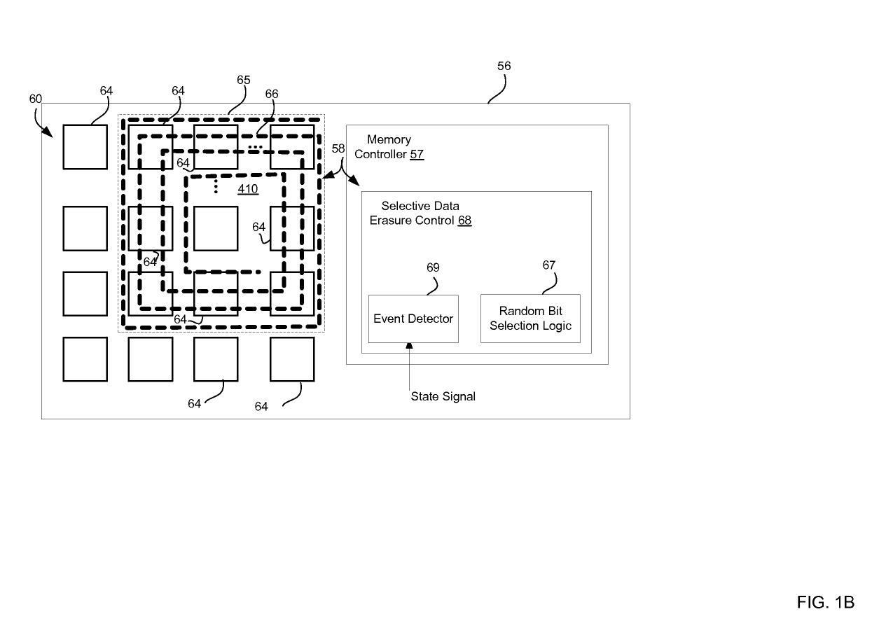

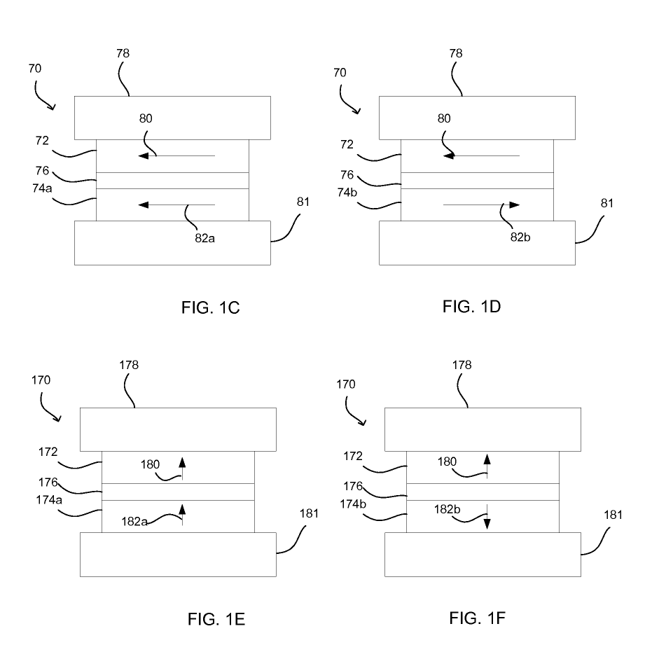

Turning to the figures, FIG. 1A is a high-level block diagram illustrating selected aspects of a system implemented, according to an embodiment of the present disclosure. System 10 may represent any of a number of electronic and/or computing devices, that may include a memory device. Such electronic and/or computing devices may include large form computing devices and small form computing devices such as a mainframe, server, personal computer, workstation, telephony device, network appliance, virtualization device, storage controller, portable or mobile devices (e.g., laptops, netbooks, tablet computers, personal digital assistant (PDAs), portable media players, portable gaming devices, digital cameras, mobile phones, smartphones, feature phones, etc.), credit cards, identity cards, key cards or component (e.g. system on a chip, processor, bridge, memory controller, memory, etc.). In alternative embodiments, system 10 may include more elements, fewer elements, and/or different elements. Moreover, although system 10 may be depicted as comprising separate elements, it will be appreciated that such elements may be integrated on to one platform, such as systems on a chip (SoCs).

In the illustrative example, system 10 comprises a processor 20 such as a microprocessor or other logic device, a memory controller 30, a memory 40 and peripheral components 50 which may include a sensitive information security circuit in accordance with the present description. The peripheral components 50 may also include, for example, a video controller, input device, output device, storage, network adapter, etc. The processor 20 may optionally include a cache 25 that may be part of a memory hierarchy to store instructions and data, and the system memory 40 may also be part of the memory hierarchy. Communication between the processor 20 and the memory 40 may be facilitated by the memory controller (or chipset) 30, which may also facilitate in communicating with the peripheral components 50.

Storage of the peripheral components 50 may be, for example, nonvolatile storage, such as solid-state drives, magnetic disk drives, optical disk drives, a tape drive, flash memory, etc. The storage may comprise an internal storage device or an attached or network accessible storage. The processor 20 is configured to write data in and read data from the memory 40. Programs in the storage are loaded into the memory and executed by the processor. A network controller or adapter enables communication with a network, such as an Ethernet, a Fiber Channel Arbitrated Loop, etc. Further, the architecture may, in certain embodiments, include a video controller configured to render information on a display monitor, where the video controller may be embodied on a video card or integrated on integrated circuit components mounted on a motherboard or other substrate. An input device is used to provide user input to the processor, and may include a keyboard, mouse, pen-stylus, microphone, touch sensitive display screen, input pins, sockets, or any other activation or input mechanism known in the art. An output device is capable of rendering information transmitted from the processor, or other component, such as a display monitor, printer, storage, output pins, sockets, etc. The network adapter may embodied on a network card, such as a Peripheral Component Interconnect (PCI) card, PCI-express, or some other I/O card, or on integrated circuit components mounted on a motherboard or other substrate.

One or more of the components of the device 10 may be omitted, depending upon the particular application. For example, a network router may lack a video controller, for example. In another example, small form factor devices such as credit cards, for example, may lack many of the components discussed above and may be limited primarily to logic and memory as well as a sensitive information security circuit as described herein.

Any one or more of the memory devices 25, 40, and the other devices 10, 20, 30, 50 may include a sensitive information security circuit in accordance with the present description. FIG. 1B shows an example of a memory 56 and a memory controller 57 having a sensitive information security circuit 58 in accordance with one embodiment of the present description. The memory 56 includes an array 60 of rows and columns of bitcells 64 of a nonvolatile memory such as, for example, a Spin Transfer Torque Random Access Memory (STTRAM) which is a type of magnetoresistive Random Access Memory (MRAM). It is appreciated that the memory 56 may be other types of nonvolatile memory which may be responsive to an on-board erasure assistance device such as a coil which provides magnetic field-assisted sensitive data erasure. It is appreciated that the memory 56 may be other types of nonvolatile memory such as NAND type flash memory, or may be a volatile memory such as a DRAM memory, for example, in applications which lack a coil type on-board erasure assistance device, for example.

The memory 56 may also include a row decoder, a timer device and I/O devices (or I/O outputs). Bits of the same memory word may be separated from each other for efficient I/O design. A multiplexer (MUX) may be used to connect each column to the required circuitry during a READ operation. Another MUX may be used to connect each column to a write driver during a WRITE operation. The memory controller 57 performs read operations, write operations and utilizes the security circuit 58 to perform sensitive information security operations to the bitcells 64 as explained below. The security circuit 58 of the controller circuit 56 is configured to perform the described operations using appropriate hardware, software or firmware, or various combinations thereof.

In one embodiment, a portion 65 of the memory 56 is a subarray of the bitcells 64 containing sensitive information. In this example, the operating system of the device has designated the subarray 65 for storing sensitive information. The size and location of the subarray 65 may vary, depending upon the particular application.

At least a portion of the bits stored in the subarray 65 may be automatically erased in response to a detected event such as entering a power up or power down state of the device, for example. Disposed over the subarray 65 is a multi-turn coil 66 (depicted in phantom in FIG. 1B) of the security circuit 58. The coil 66 may be fabricated within the upper metal layers disposed over the bitcells of the memory. In one embodiment, the coil 66 may be positioned only over the subarray 65 selected to contain the sensitive information. In other embodiments, one or more such coils 66 may be disposed over other portions of the memory.

The coil 66 is controlled by a selective data erasure control 68 of the security circuit 58. The coil 66 functions as an on-board erasure assistance device and provides magnetic field-assisted sensitive data erasure for bitcells 64 of the subarray 65 containing the sensitive information.

In the illustrated embodiment, an event detector 69 of the selective data erasure control 68, detects an event which may be used by the selective data erasure control 68 to trigger automatic erasure of sensitive information stored in the subarray 65 in response to the detected event. For example, when entering a power down mode as indicated by a state signal input by the event detector 68, the selective data erasure control 68 powers the coil 66 to generate a magnetic field directed through the bitcells 64 of the subarray 65 to assist in the erasure of at least some of the bits representing the sensitive information stored in the subarray 65. In addition, the selective data erasure control 68 directs write current to selected bitcells 64 of the subarray 65 to erase at least some of the bits representing the sensitive information stored in the subarray 65, with the assistance of the magnetic field provided by the coil 66. In other embodiments, sensitive data erasure may be initiated manually by the authorized user to reset bits with appropriate write current and an on-board erasure assistance device such as the coil 66.

In one embodiment in which the sensitive data is stored in the subarray 65 (FIG. 1B) of the memory 56, the portion of bits which are reset to erase sensitive data may be randomly distributed over the subarray 65. Such a random distribution of reset bits of sensitive data is believed to enhance prevention of unauthorized recovery of the sensitive data. It is recognized that random distribution of reset bits of sensitive data may be achieved in a variety of techniques, depending upon the particular application.

For example, it is recognized that the rate of variation in regions and subregions of memory devices is often increasing. Thus, the physical characteristics of individual bitcells of an array of bitcells in a memory may vary from bitcell to bitcell as a result of variations encountered in typical memory fabrication processes. For example, in MRAM memory devices having MTJ bitcells, one such physical characteristic which may randomly vary from MTJ bitcell to bitcell is the level of write current at which a particular MTJ bitcell may be reset from one state to another. Another physical characteristic which may randomly vary from bitcell to bitcell is the speed at which a particular MTJ bitcell may be reset from one state to another. Thus, a percentage of the MTJ bitcells of an array or subarray may be reset relatively quickly with a very low write current, and are referred to herein as “weak bitcells.” These weak bitcells may be randomly distributed over the array.

In accordance with one aspect of the present description, the variation from bitcell to bitcell may be utilized to permit application of a relatively small write to achieve random erasure of bitcells. More specifically, the low write current may be sufficient to reset a random distribution of some bitcells of the subarray 65 but insufficient to reset other bitcells of the subarray 65 which require a higher write current for reset. Hence applying very low write current which may be applied over a relatively short period of time in conjunction with a disturbing magnetic field of an on-board erasure assistance device in one embodiment, can flip the contents of weak bitcells randomly distributed over the subarray 65. Consequently bits of sensitive information stored in the subarray 65 may be randomly flipped across the subarray 65 of the memory. If enough bits are flipped, the sensitive information content may be made more difficult if not impractical to recover. In this manner, write current and write time for sensitive data erasure may be correspondingly reduced.

In another aspect of the present description, random distribution of reset bits to protect against unauthorized recovery of sensitive data may be achieved by an on-board randomization circuit 67 in some embodiments. In response to detection of an event such as a power shutdown or power-up process, the randomization circuit may randomly select bits of the sensitive data to be reset.

In the illustrated embodiment, each bitcell 64 of the array 60 of bitcells 64 includes a ferromagnetic device 70 (FIG. 1C) such as a spin valve, or a magnetic tunnel junction (MTJ) device. Each ferromagnetic device 70 of a bitcell comprises two layers 72, 74a of ferromagnetic material separated by an intermediate layer 76 which is a metallic layer in the case of a spin valve or is a thin dielectric or insulating layer in the case of an MTJ. In this example, the layer 72 of ferromagnetic material is contacted by an electrical contact layer 78 and has a fixed polarization in which the magnetization direction which predominates, is fixed. Hence, the layer 72 is referred to as the fixed layer. The predominant magnetization direction of the fixed layer 72 has a magnetization direction represented by an arrow 80 pointing from right to left in the cross-sectional view of FIG. 1C.

The other layer 74a of ferromagnetic material is contacted by an electrical contact layer 81 and is referred to as the “free layer” which has a changeable polarization in which the predominant magnetization direction of the free layer may be selectively changed. The predominant magnetization direction of the free layer 74a is represented by an arrow 82a which also points from right to left in the cross-sectional view of FIG. 1C.

In the example of FIG. 1C, the predominant magnetization directions of both the free and fixed layers 74a, 72 are depicted as being the same, that is in the same direction. If the predominant magnetization directions of the two ferromagnetic layers 72, 74a are the same, the polarizations of the two layers are referred to as being “parallel.” In the parallel polarization, the bitcell exhibits a low resistance state which may be selected to represent one of a logical one or a logical zero stored in the bitcell. If the predominant magnetization directions of the two ferromagnetic layers are opposite as shown by the arrows 80 (right to left) and 82b (left to right) in FIG. 1D, the polarizations of the two layers 72, 74b are referred to as being “anti-parallel.” In the anti-parallel polarization, the bitcell exhibits a high resistance state which may be selected to represent the other one of a logical one or a logical zero stored in the bitcell.

The polarization and hence the logical bit value stored in a bitcell 64 of an STTRAM 66 may be set to a particular state by passing a spin polarized current in a particular direction through the ferromagnetic device 70 of the bitcell 64. A spin polarized current is one in which the spin orientations of the charge carriers (such as electrons) are predominantly of one type, either spin up or spin down. Thus, the control circuit 57 (FIG. 1B) is configured to store a logical one in a bitcell 64 of an STTRAM 66 by passing spin polarized current in one direction through the ferromagnetic device 70 of the bitcell 64. As a result, the ferromagnetic layers of the ferromagnetic device 70 of the bitcell 64 have a polarization which is one of parallel or antiparallel, depending upon which polarization state has been selected to represent a logical one.

Conversely, a logical zero may be stored in a bitcell 64 of an STTRAM 66 by the control circuit 57 passing spin polarized current in the opposite direction through the ferromagnetic device 70 of the bitcell. As a result, the ferromagnetic layers of the ferromagnetic device 70 of the bitcell 64 have a polarization which is the other of parallel or antiparallel, depending upon which polarization has been selected to represent a logical zero.

FIGS. 1E and 1F depict an alternative embodiment of a ferromagnetic device. Here, each bitcell 64 of the array 60 of bitcells 64 includes a ferromagnetic device 170 (FIG. 1E) such as a spin valve, or a magnetic tunnel junction (MTJ) device. Each ferromagnetic device 170 of a bitcell comprises two layers 172, 174a of ferromagnetic material separated by an intermediate layer 176 which is a metallic layer in the case of a spin valve or is a thin dielectric or insulating layer in the case of an MTJ. In this example, the layer 172 of ferromagnetic material is contacted by an electrical contact layer 178 and has a fixed polarization in which the magnetization direction which predominates, is fixed. This fixed layer is usually much thicker than the free layer. Hence, the layer 172 is referred to as the fixed layer. The predominant magnetization direction of the fixed layer 172 is represented by an arrow 180 pointing from bottom to top in the cross-sectional view of FIG. 1E.

The other layer 174a of ferromagnetic material is contacted by an electrical contact layer 181 and is referred to as the “free layer” which has a changeable polarization in which the predominant magnetization direction of the free layer may be selectively changed. The predominant magnetization direction of the free layer 174a is represented by an arrow 182a which also points from bottom to top in the cross-sectional view of FIG. 1E.

In the example of FIG. 1E, the predominant magnetization directions of both the free and fixed layers 174a, 172 are depicted as being the same, that is in the same direction. If the predominant magnetization directions of the two ferromagnetic layers 172, 174 are the same, the polarizations of the two layers are referred to as being “parallel.” In the parallel polarization, the bitcell exhibits a low resistance state which may be selected to represent one of a logical one or a logical zero stored in the bitcell. If the predominant magnetization directions of the two ferromagnetic layers are opposite as shown by the arrows 180 (bottom to top) and 182b (top to bottom) in FIG. 1F, the polarizations of the two layers 172, 174b are referred to as being “anti-parallel.” In the anti-parallel polarization, the bitcell exhibits a high resistance state which may be selected to represent the other one of a logical one or a logical zero stored in the bitcell.

The polarization and hence the logical bit value stored in a bitcell 64 of an STTRAM 66 may be set to a particular state by the control circuit 57 which is configured to pass a spin polarized current in a particular direction through the ferromagnetic device 170 of the bitcell 64. Thus, a logical one may be stored in a bitcell 64 of an STTRAM 66 by passing spin polarized current in one direction through the ferromagnetic device 170 of the bitcell 64. As a result, the ferromagnetic layers of the ferromagnetic device 170 of the bitcell 64 have a polarization which is one of parallel and antiparallel, depending upon which polarization has been selected to represent a logical one.

Conversely, a logical zero may be stored in a bitcell 64 of an STTRAM 66 by the control circuit 57 passing spin polarized current in the opposite direction through the ferromagnetic device 170 of the bitcell. As a result, the ferromagnetic layers of the ferromagnetic device 170 of the bitcell 64 have a polarization which is the other of parallel and antiparallel, depending upon which polarization has been selected to represent a logical zero.

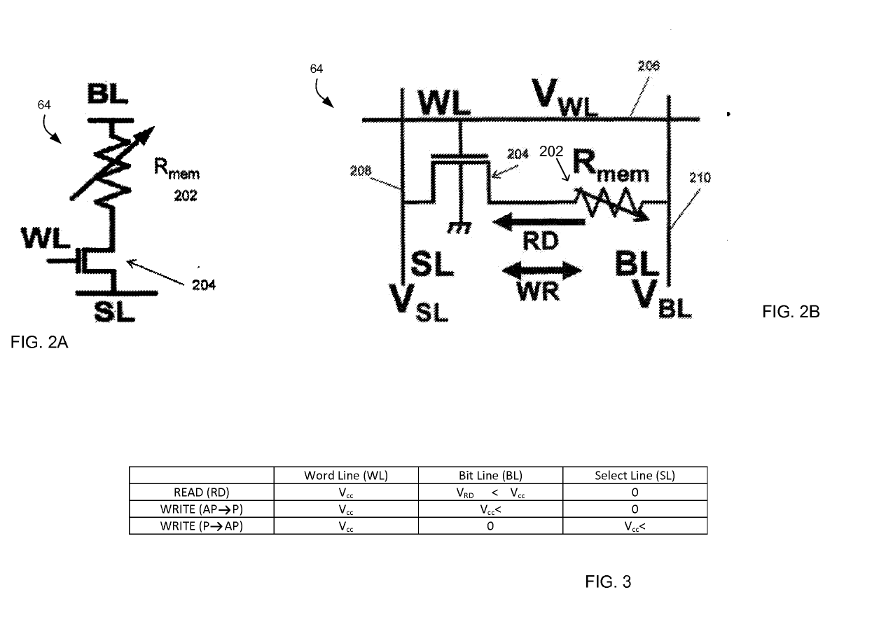

STTRAM uses a special write mechanism based on spin polarization current induced magnetization switching. FIGS. 2A-2B show schematics of the basic elements of a typical STTRAM bit cell 64, comprising a switching transistor 204 and a variable resistive transistor element Rₘₑₘ (element 202). The combined structure is frequently referred to as a 1T1R (one transistor one resistor) cell. Bit-line (BL, element 210), word line (WL, element 206), and source-line or select line (SL, element 208) for the bitcell are shown more prominently in FIG. 2B, with corresponding voltages, V_{BL}, V_{WL}, and V_{SL} respectively. The transistor 204 acts as a selector switch, while the resistive element 202 may be a magnetic tunnel junction (MTJ) device such as the device 70 (FIG. 1C, 1D), comprising two soft ferromagnetic layers 72, 74a (or 74b), layer 72 having a fixed ‘reference’ magnetization direction 80, and the other having a variable magnetization direction 82a, 82b, separated by a junction layer 76. FIG. 2B shows while there is only one read direction (the arrow labeled RD), the write operation can be bi-directional (the double-headed arrow labeled WR). Therefore, this 1T1R structure can be described as a 1T-1STT MTJ memory cell with unipolar ‘read’ and bipolar ‘write.’ The bitcell 64 is read by precharging the bit line BL to V_{RD} and allowing it to decay through the cell when the word line WL is strobed with the voltage V_{cc}, as shown in the chart of FIG. 3, which turns on the switching transistor 204.

In this example, a logical zero is represented by a high resistance state (antiparallel polarization (FIG. 1D, 1F) of the variable resistive transistor element Rₘₑₘ (element 202) which is the magnetic tunnel junction (MTJ) device 70, 170. Conversely a logical one is represented in this example by a low resistance state (parallel polarization (FIG. 1C, 1E) of the variable resistive transistor element Rₘₑₘ (element 202) which is the magnetic tunnel junction (MTJ) device 70, 170. Accordingly, if the read voltage V_{RD} decays to a relatively high value, a logical 0 (high resistance state) is indicated as being stored in the MTJ device 70, 170. Conversely, if the precharge voltage V_{RD} decays to a relatively low value, a logical 1 (low resistance state) is indicated as being stored in the MTJ device 70, 170. (It is appreciated that in other embodiments, a logical 0 may be represented by a low resistance state (parallel polarization (FIG. 1C, 1E) of the variable resistive transistor element Rₘₑₘ (element 202). Conversely a logical 1 may be represented by a high resistance state (anti-parallel polarization (FIG. 1D, 1F) of the variable resistive transistor element Rₘₑₘ (element 202).)

To write into the bitcell 64, a bidirectional writing scheme controlled by the control circuit 68 (FIG. 1B) is used. To write a logical 1 in which the state of the variable resistive transistor element Rₘₑₘ (element 202) changes from the anti-parallel state (FIG. 1D, 1F) to the parallel state (FIG. 1C, 1D), bit line BL is charged to V_{cc} and source line SL is connected to ground so that a current is flowing from the bit line BL to the source line SL. Conversely, to write a logical 0 in which the state of the variable resistive transistor element Rₘₑₘ (element 202) changes from the parallel state (FIG. 1C, 1E) to the anti-parallel state (FIG. 1D, 1F), a current with opposite direction is utilized. Accordingly, source line SL at V_{cc} and bit line BL at ground causes current to flow from the source line SL to the bit line BL, the opposite direction.

It is appreciated herein that changing the magnetic polarization of the bitcell 64 from one state to the other state is asymmetrical. More specifically, it is appreciated that the write time to change the state of the bitcell 64 from the parallel state (FIG. 1C, 1E) to the anti-parallel state (FIG. 1D, 1F) can in some instances be substantially longer than the write time for the converse, that is, the write time to change the state of the bitcell 64 from the anti-parallel state (FIG. 1D, 1F) to the parallel state (FIG. 1C, 1E). Accordingly, the write time behavior is asymmetric in many applications.

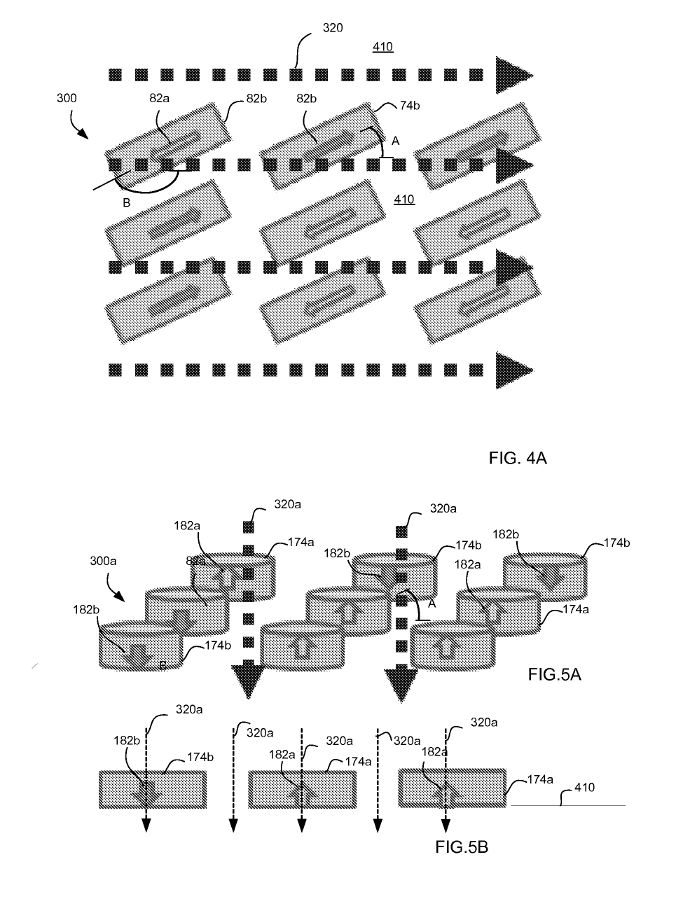

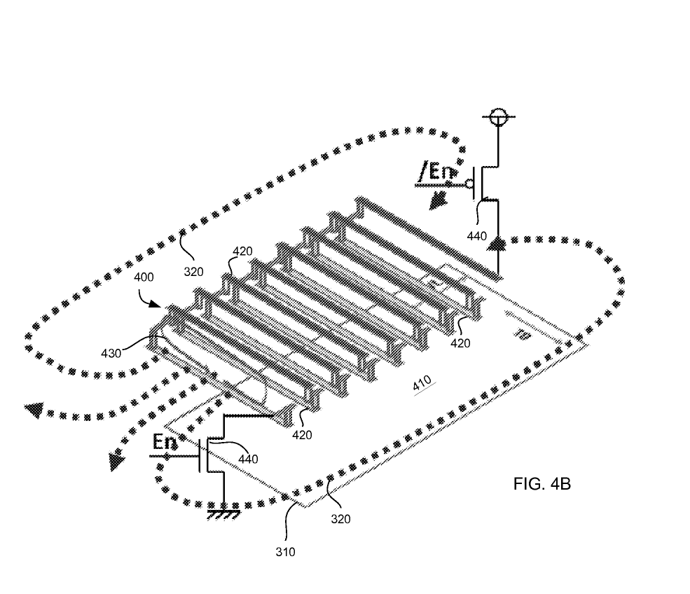

In accordance with one aspect of the present description it is appreciated that the write time for a bit erasure such as a parallel to anti-parallel state change, for example, may be substantially reduced by directing a magnetic field through the bitcell 64 as the appropriate write current is directed through the bitcell to change its state from the parallel state to the anti-parallel state. FIG. 4A is a schematic representation of a subarray 300 of free ferromagnetic layers 74a, 74b of the MTJ devices 70 (FIG. 1C, 1D) of a subarray 65 (FIG. 1B) of bitcells 64 of the array 60. A magnetic field as represented by the magnetic field lines 320 is directed through the free layers 74a, 74b of the MTJ devices 70 (FIG. 1C, 1D) of the subarray 65 (FIG. 1B) of bitcells 64 of the array 60. In the illustrated embodiment, the magnetic field 320 is in substantial parallel alignment with the magnetization direction of the antiparallel polarized ferromagnetic layers 74b (FIG. 1D) as represented by the arrows 82b. By substantial parallel alignment, it is meant that the angular difference A between the field lines of the magnetic field 320 passing through the bitcells of the subarray 65, and the magnetization direction 82b of the free ferromagnetic layers 74b of the antiparallel polarization is within a range of 0-90 degrees, such as approximately 45 degrees in one embodiment.

Conversely, in the illustrated embodiment, the magnetic field 320 is in substantial anti-parallel alignment with the magnetization direction of the parallel polarized ferromagnetic layers 74a (FIG. 1C) as represented by the arrows 82a. By substantial anti-parallel alignment, it is meant that the angular difference B between the field lines of the magnetic field 320 passing through the bitcells of the subarray 65, and the magnetization direction 82a of the free ferromagnetic layers 74a of the parallel polarization is within a range of 90-180 degrees, such as approximately 135 degrees, in one embodiment. Such an arrangement is believed to facilitate a state change from parallel polarization (FIG. 1C) to anti-parallel polarization (FIG. 1D) such the write current for data erasure may be reduced, or the write time for data erasure to be reduced, or both when changing the polarization state from the parallel polarization state to the anti-parallel polarization state of the MTJ device 70 of each bitcell 64 through which the magnetic field 320 is directed. Similarly, such an arrangement is believed to facilitate a state change from anti-parallel polarization (FIG. 1D) to parallel polarization (FIG. 1C) such the write current for data erasure may be reduced, or the write time for data erasure to be reduced, or both when changing the polarization state from the anti-parallel polarization state to the parallel polarization state of the MTJ device 70 of each bitcell 64 through which the magnetic field 320 is directed.

FIG. 4B shows an example of a multi-turn electro-magnet coil 400 of an disposed over the subarray 65 of bitcells 64 (FIG. 1B) of the memory array 60. The subarray 65 of bitcells 64 (FIG. 1B) defines a plane 410, and in this embodiment, each turn 420 of the coil 400 is positioned orthogonal to the bitcell plane 410 so that the field lines 320 of the magnetic field are directed through the bitcells of the subarray 65 in substantial alignment with the bitcell plane 410. By substantial alignment, it is meant that the angular difference between the bitcell plane 410 and the field lines of the magnetic field 320 passing through the bitcell subarray 65 is within a range of 45 to −45 degrees, such as approximately 0 degrees, in one embodiment.

The multi-turn coil 400 may be fabricated using a variety of techniques. One such technique forms the multi-turn coil using metallization layers, vias and lateral conduits. Other techniques may form the multi-turn coil using other conductive materials such as doped semiconductor materials. In the illustrated embodiment, each turn 420 is formed of spaced conductive layers which are linked with spaced conductive vias. Adjacent turns are linked with spaced lateral conduits. Yet another technique for fabricating the multi-turn coil may include metallization and through silicon vias (TSVs) that are frequently used for three dimensional integrated circuit stacking. It is appreciated that a suitable coil may have fewer or a greater number of turns, may have other shapes and other positions, depending upon the particular application.

To generate the magnetic field 320, a drive current is passed through the turns 420 of the electro-magnet coil 400 in a counter-clockwise direction as indicated by the arrow 430. A magnetic field directed in the opposite direction may be generated by passing a drive current through the turns 420 of the coil 400 in a clockwise direction. The drive current may be selectively switched on and off by the control circuit 57 (FIG. 1B) which is configured to provide appropriate enable signals (En, /En) to switching transistors 440. In the illustrated embodiment, the drive current to the coil 400 may be switched on to at least partially coincide with the write current switching the bitcells of the subarray 65 from the parallel polarization state to the antiparallel polarization state (or vice versa) to provide magnetic assistance to the state change.

Generally, many kinds of semiconductor chips have Power-On Reset (POR) or Power-Good (PG) signal. Such a signal is generally generated internally during the power-up process or is received from the system or the controller. Accordingly, in one embodiment, the enable signals (En, /En)) to switching transistors 440 may be derived directly from power mode signals such as Power-On Reset (POR) or Power-Good (PG) signals so that the coil 400 is powered on upon initiation of a power down or power up condition, as appropriate.

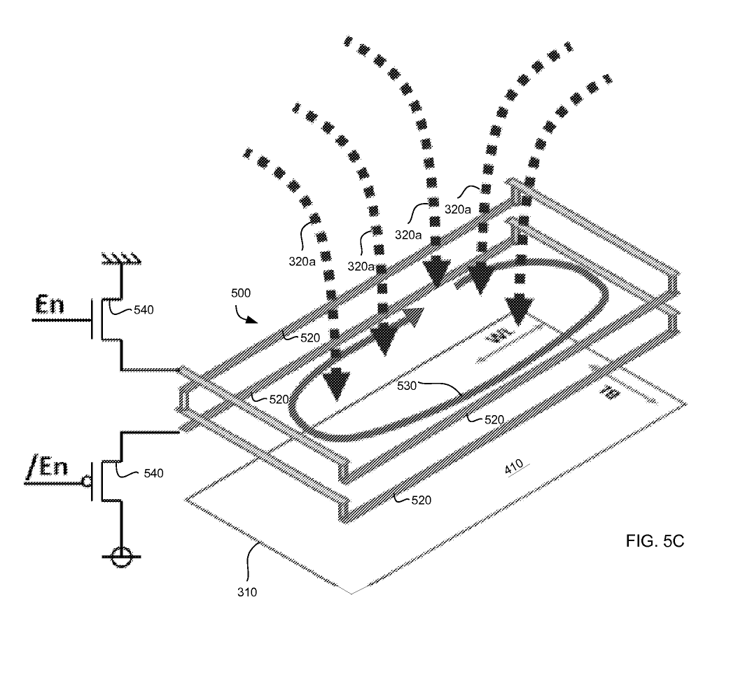

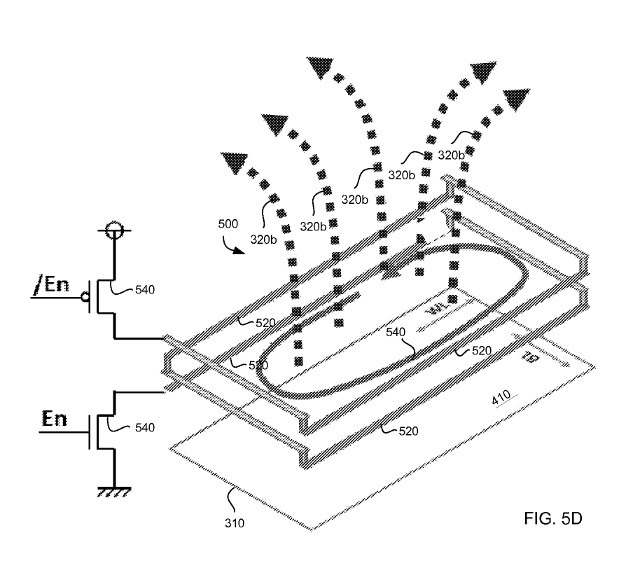

FIG. 5A and the cross-sectional view of FIG. 5B are a schematic representation of an alternative embodiment of a subarray 300a of free ferromagnetic layers 174a, 174b of the MTJ devices 170 (FIG. 1E, 1F) of a subarray 65 (FIG. 1B) of bitcells 64 of the array 60. A magnetic field as represented by the magnetic field lines 320a is directed through the free layers 174a, 174b of the MTJ devices 170 (FIG. 1E, 1F) of the subarray 65 (FIG. 1B) of bitcells 64 of the array 60. In the illustrated embodiment, the magnetic field 320a is generally orthogonal to the bitcell plane 410 (FIG. 1B) and is in substantially parallel alignment with the magnetization direction of the antiparallel polarized ferromagnetic layers 174b (FIG. 1F) as represented by the arrows 182b. By substantial parallel alignment, it is meant that the angular difference between the field lines of the magnetic field 320a passing through the bitcells of the subarray 300a, and the magnetization direction 182b of the free ferromagnetic layers 174b of the antiparallel polarization is within a range of 45 to −45 degrees, in one embodiment. In the embodiment depicted in FIGS. 5A, 5B, the angular difference between the field lines of the magnetic field 320a passing through the bitcells of the subarray 65, and the magnetization direction 182b of the free ferromagnetic layers 174b of the antiparallel polarization is substantially zero.

Conversely, in the illustrated embodiment, the magnetic field 320a is in substantial anti-parallel alignment with the magnetization direction of the parallel polarized ferromagnetic layers 174a (FIG. 1E) as represented by the arrows 182a. By substantial anti-parallel alignment, it is meant that the angular difference between the field lines of the magnetic field 320 and the magnetization direction 182a of the free ferromagnetic layers 174a of the parallel polarization is within a range of 135 to 225 degrees, in one embodiment. In the embodiment depicted in FIG. 5A, 5B, the angular difference between the field lines of the magnetic field 320a passing through the bitcells of the subarray 65, and the magnetization direction 182a of the free ferromagnetic layers 174b of the parallel polarization is substantially 180 degrees. Such an arrangement is believed to facilitate a state change from parallel polarization (FIG. 1E) to anti-parallel polarization (FIG. 1F) such the write current may be reduced, or the write time reduced, or both when changing the polarization state from the parallel polarization state to the anti-parallel polarization state of the MTJ device 170 of each bitcell 64 through which the magnetic field 320a is directed.

FIG. 5C shows an example of a multi-turn electromagnet coil 500 disposed over the subarray 65 of bitcells 64 (FIG. 1B) of the memory array 60. The subarray 65 of bitcells 64 (FIG. 1B) defines a plane 410, and in this embodiment, each turn 520 of the coil 500 is positioned parallel to the bitcell plane 410 so that the field lines 320a of the magnetic field are directed substantially orthogonally through the bitcell plane 410 of the bitcells of the subarray 65. By substantially orthogonal, it is meant that the angular difference between the bitcell plane 410 and the field lines of the magnetic field 320a passing through the bitcell subarray 65 is greater than 45 degrees, in one embodiment. In another embodiment, the angular difference between the bitcell plane 410 and the field lines of the magnetic field 320a passing through the bitcell subarray 65 is approximately 90 degrees.

The multi-turn coil 500 may be fabricated using a variety of techniques. One such technique forms the multi-turn coil using metallization layers, vias and lateral conduits. Other techniques may form the multi-turn coil using other conductive materials such as doped semiconductor materials. In the illustrated embodiment, each turn 520 is formed of spaced conductive layers which are linked with spaced conductive vias and spaced lateral conduits. Adjacent turns are linked with spaced vias. Yet another technique for fabricating the multi-turn coil may include metallization and through silicon vias (TSVs) that are frequently used for three dimensional integrated circuit stacking. It is appreciated that a suitable coil may have fewer or a greater number of turns, may have other shapes and other positions, depending upon the particular application.

To generate the magnetic field 320a, a drive current is passed through the turns 520 of the coil 500 in a clockwise direction as indicated by the arrow 530. A magnetic field 320b (FIG. 5D) directed in the opposite direction may be generated by passing a drive current 540 through the turns 520 of the coil 500 in a counter-clockwise direction. The drive current may be selectively switched on and off by the control circuit 57 (FIG. 1B) which is configured to provide appropriate enable signals (En, En (bar)) to switching transistors 540. In the illustrated embodiment, the drive current to the coil 500 may be switched on to at least partially coincide with the write current switching the bitcells of the subarray 65 from the parallel polarization state to the antiparallel polarization state to provide magnetic assistance to the state change.

In the examples described above, some or all of the bitcells 64 (FIG. 1B) of an entire subarray 65 may be switched to one of the parallel polarization state (FIGS. 1C, 1E) or the anti-parallel polarization state (FIGS. 1D, 1F) to erase bits of sensitive information using the magnetic assistance provided by the associated magnetic field 320, 320a, 320b. For simplicity sake, the subarray 65 of FIG. 1B is depicted as including a 3 by 3 subarray of bitcells. It is appreciated that the number of bitcells for which an assistive magnetic field may be used to switch at one time the respective polarization states from the parallel to anti-parallel polarizations, may vary, depending upon the particular application. In that modern memories often have the capacity to store many gigabytes (or more) of data, the subarray 65 may include one bitcell, or may include tens, hundreds, thousands, tens of thousands or more bitcells for which their respective polarization states are switched from the parallel to anti-parallel polarizations at one time using magnetic assistance as described herein.

In the illustrated embodiment, the anti-parallel polarization, high-resistance state, is selected to represent a logical zero stored in the bitcell. Accordingly, logical zeroes may be written into bitcells of the subarray 65, effectively “erasing” any data stored in those bitcells of the subarray 65. Any bitcells which were already in the anti-parallel polarization, high-resistance state before the erase operation applied to the subarray 65, remain in the anti-parallel polarization, high-resistance state after the erase operation. The control circuit 57 is configured to erase some or all of the subarray of bitcells by providing the magnetic assistance and the appropriate parallel to antiparallel state change write currents through each bitcell of the subarray 65 as described above.

In the illustrated embodiment, the parallel polarization, low-resistance state, is selected to represent a logical one stored in the bitcell. Accordingly, logical ones may be written into bitcells of the subarray 65, effectively “erasing” any data stored in those bitcells of the subarray 65. Any bitcells which were already in the parallel polarization, low-resistance state before the erase operation applied to the subarray 65, remain in the parallel polarization, low-resistance state after the erase operation. The control circuit 57 is configured to erase some or all of the subarray of bitcells by providing the magnetic assistance and the appropriate anti-parallel to parallel state change write currents through bitcells of the subarray 65 as described above.

In the illustrated embodiment, the parallel polarization, low-resistance state, is selected to represent a logical one stored in the bitcell. Hence, to write a logical one into a bitcell which is initially in the anti-parallel polarization, high-resistance state representing a logical zero, an appropriate antiparallel to parallel state change write current is driven through the particular bitcell to switch the polarization state of the bitcell from anti-parallel to parallel. As previously mentioned, switching the polarization state of an STT bitcell from anti-parallel to parallel typically requires substantially less write time and power as compared to switching the polarization state of an STT bitcell from parallel to anti-parallel polarization. Accordingly, in one embodiment, an assistive magnetic field may be omitted when writing logical ones to switch the polarization state of the bitcell from anti-parallel to parallel. It is appreciated that in other embodiments, appropriate assistive magnetic fields may be directed through bitcells for both state changes, that is, from parallel to anti-parallel polarization, and vice versa. It is further appreciated that in other embodiments, the anti-parallel polarization, high-resistance state, may be selected to represent a logical one stored in the bitcell, and the parallel polarization, low-resistance state, may be selected to represent a logical zero stored in the bitcell.

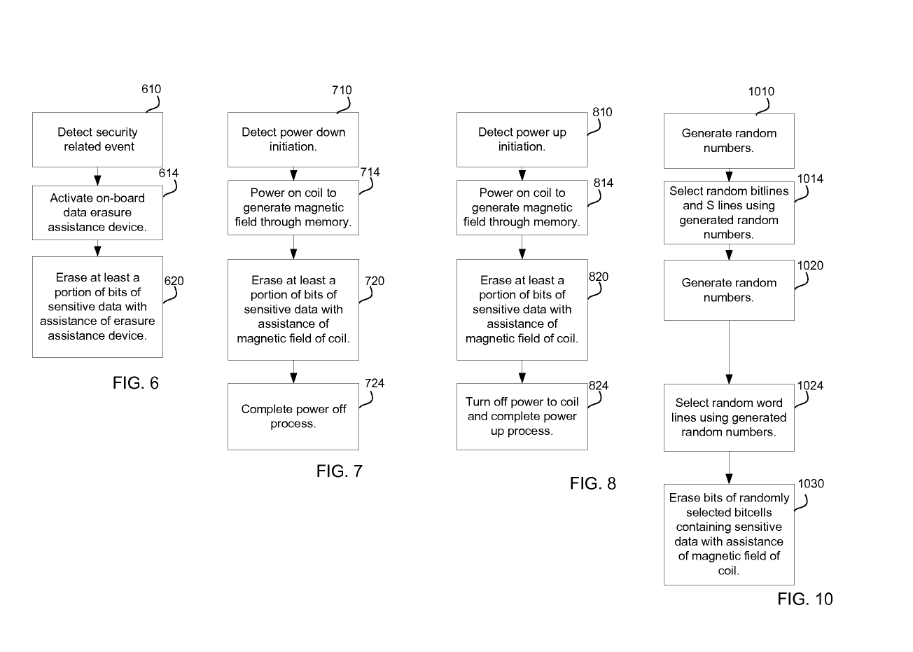

FIG. 6 shows one example of operations of a device such as a microprocessor controlled device 10 of FIG. 1 in which a security related event is detected (block 610). As previously mentioned, examples of such security related events may be initiation of a power down or power up sequence of the device. Upon detection of a security related event, an on-board data erasure assistance device may be activated (block 614). The coils 66 (FIG. 1B), 400 (FIG. 4B), and 500 (FIGS. 5C, 5D) are examples of on-board data erasure assistance devices which may be disposed over a subarray 65, 410 of bitcells storing sensitive information. It is appreciated that other data erasure assistance devices may be provided, depending upon the particular application.

In association with the activation of the on-board data erasure assistance device, at least a portion of the bits representing sensitive data stored in the subarray may be erased (block 620). As previously mentioned, it is believed that erasure of bits of sensitive information may be achieved more quickly, or at lower write current levels, or both, by utilizing the on-board data erasure assistance device. Upon erasure of some or all of the sensitive information stored in the subarray, it is believed that unauthorized recovery of the sensitive information is prevented or rendered more difficult as to be impractical in many applications.

FIG. 7 shows another example of operations of a device such as a microprocessor controlled device 10 of FIG. 1 in which a security related event is detected. In this example, the security related event is the detection of the initiation of a power down condition (block 710). As previously mentioned, such a power down condition may be indicated by the state of a power-on reset (POR) signal or power good (PG) signal, for example. Thus, as the POR signal transitions from an active to inactive state, the initiation of a power down process may be detected (block 710). It is appreciated that other signals may be monitored to detect initiation of a power down condition.

Upon detection of the beginning of a power down process in which the power to the logic and memory circuits of the device will be terminated, an on-board data erasure assistance device may be activated (block 714) before power is completely removed. Again, the coils 66 (FIG. 1B), 400 (FIG. 4B), and 500 (FIGS. 5C, 5D) are examples of on-board data erasure assistance devices which may be disposed over a subarray 65, 410 of bitcells storing sensitive information. In association with the activation of the on-board data erasure assistance device, write current is provided to the subarray so that at least a portion of the bits representing sensitive data stored in the subarray may be erased (block 720) and the power down process is completed (block 724). Here too, upon erasure of some or all of the sensitive information stored in the subarray, it is believed that unauthorized recovery of the sensitive information is prevented or rendered more difficult as to be impractical in many applications.

It is recognized herein that a power down condition may occur in a variety of circumstances. In one example, the power down condition may be entered in a controlled and authorized manner in which a power down sequence is controlled by the system or CPU of the device in an expected manner. Conversely, in some applications the power down condition may be entered suddenly and unexpectedly such as upon exhaustion of the battery powering the device, for example. Accordingly, it is appreciated that in some circumstances, the opportunity to detect a power down condition and to conduct a sensitive information erasure process in response to that power down detection, may be reduced or eliminated in some power down events such that the system does not have sufficient time to complete or perhaps even initiate the sensitive information erasure process.

FIG. 8 shows yet another example of operations of a device such as a microprocessor controlled device 10 of FIG. 1 in which a security related event is detected. In this example, the security related event is the detection of the initiation of a power up condition (block 810). Accordingly, should the sensitive erasure process not be completed or initiated during a prior power down event, the sensitive data erasure process may be initiated and/or completed in response to a subsequent power up event.

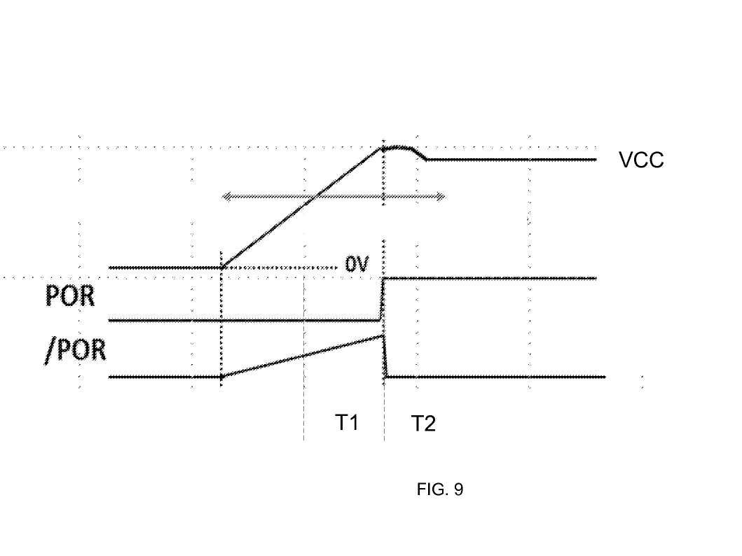

As previously mentioned, such a power up condition may be indicated by the state of a power-on reset (POR) signal or power good (PG) signal, for example. FIG. 9 shows an example in which a power signal which supplies power to logic or memory circuits transitions from a low voltage state, such as zero volts, for example, to a higher voltage state, represented as VCC, in this example. Prior to the power signal stabilizing at the voltage level VCC, a power-on reset (POR) signal is at a low logic state as shown in FIG. 9. As the power signal stabilizes at the voltage level VCC, the power-on reset (POR) signal transitions to the high logic state. Typically, the memory may be read upon the power-on reset (POR) signal reaching the high logic state. In one aspect of the present invention, sensitive information is erased prior to the power reaching the level at which the memory is permitted to be read.

In this embodiment, a related power state signal /POR, is similarly at a logic low state when the power signal is at zero volts. However, as the power signal POR transitions to the higher voltage level VCC, the power state signal /POR also transitions towards the logic high state. However, once the power state signal POR transitions to the high logic state, the related power state signal /POR transitions back to the logic low state. As a result, there is an interval of time T1 in which the power state signals POR and /POR are at a logical low and a logical high states, respectively. Accordingly, the power state signals POR and /POR may be used as the coil enable signals /EN and EN, respectively, to turn the on-board erasure assistance coil 400 (FIG. 4B) on during the time interval T1 which occurs in the power up process depicted in FIG. 9 before the power state signal POR reaches the logic one state. The power state signals POR and /POR may similarly be used to turn the on-board erasure assistance coils 66 (FIG. 1B), and 500 (FIGS. 5C, 5D) on during the time interval T1 which occurs in the power up process depicted in FIG. 9. In many applications, the power ramp-up time T1 may be in the microsecond to millisecond range. It is appreciated that in other applications, the power ramp-up time T1 may vary.

In association with the activation of an on-board data erasure assistance device such as the coils 66, 400, 500, for example, at least a portion of the bits representing sensitive data stored in the subarray may be erased (block 820) using suitable write currents to bitcells of the subarray containing the sensitive information. Here too, upon erasure of some or all of the sensitive information stored in the subarray, it is believed that unauthorized recovery of the sensitive information is prevented or rendered more difficult as to be impractical in many applications.

As the power signal stabilizes at the higher voltage level VCC, the power state signals POR and /POR switch logic states such that the power state signals POR and /POR signal are at the logical high and logical low states, respectively. Accordingly, the power state signals POR and /POR may again be used as the coil enable signals /EN and EN, respectively, to turn the on-board erasure assistance coil 400 (FIG. 4B) off (block 824) during the time interval T2 which occurs upon completion of the power up process depicted in FIG. 9. The power state signals POR and /POR may similarly be used to turn the on-board erasure assistance coils 66 (FIG. 1B), and 500 (FIGS. 5C, 5D) off during the time interval T2 which occurs following completion of the power up process depicted in FIG. 9.

FIG. 10 is a more detailed example of the operations 620 (FIG. 6), 720 (FIG. 7), 820 (FIG. 9) in which at least a portion of bits of sensitive data are erased with assistance of erasure assistance device. As previously mentioned, in some embodiments, satisfactory levels of data protection may be achieved by erasing some but not all bits of the data representing the sensitive information. It is believed that such security may be enhanced by randomly selecting the bits of the sensitive information to be erased.

In one embodiment, random selection of bits may be achieved by relying upon random variations in fabrication processes which results in the specifications of the bitcells of the subarray having a random distribution such that weak bitcells may be randomly distributed among stronger bitcells. Accordingly, erasure of random bits may be achieved by applying a relatively weak write current sufficient to flip the bits of the randomly distributed weak bitcells.

FIG. 10 is directed to another embodiment in which bitcells may be selected at random to reset the bits stored in those randomly selected bitcells. In one operation, one or more random numbers are generated (block 1010). As a function of those randomly selected numbers, random bitlines BL and random source lines SL of an array or subarray storing sensitive information are randomly selected (block 1014). In another operation, one or more random numbers are again generated (block 1020). As a function of those additional randomly selected numbers, random word lines WL of the array or subarray storing sensitive information are randomly selected (block 1024). In association with the activation of an on-board data erasure assistance device such as the coils 66, 400, 500, for example, at least a portion of the bits representing sensitive data stored in the subarray may be erased (block 1030) using suitable write currents to the randomly selected bitcells of the subarray containing the sensitive information. Here too, upon erasure of the randomly selected bits of the sensitive information stored in the subarray, it is believed that unauthorized recovery of the sensitive information is prevented or rendered more difficult as to be impractical in many applications.

### Examples

The following examples pertain to further embodiments.

Example 1 is an apparatus, comprising:

a memory configured to store sensitive information in at least a portion of the memory;

a detector configured to detect a security event; and

a controller coupled to the detector and memory, said controller configured to protect sensitive information stored as data in the at least a portion of the memory, including said controller configured to, in response to said detector detecting a first security event, change bits of said data of said sensitive information to prevent recovery of at least a portion of said sensitive information by reading said portion of said memory.

In Example 2, the subject matter of Examples 1-8 (excluding the present Example) can optionally include that said detector is configured to detect as a security event, initiation of one of power up and power down conditions of the apparatus.

In Example 3, the subject matter of Examples 1-8 (excluding the present Example) can optionally include that said memory is nonvolatile and said controller is configured to direct write current to said nonvolatile memory to change bits of said data of said sensitive information to prevent recovery of at least a portion of said sensitive information.

In Example 4, the subject matter of Examples 1-8 (excluding the present Example) can optionally include that said memory is nonvolatile, said apparatus further comprising an on-board erasure assistance apparatus coupled to said controller, said controller configured activate the on-board erasure assistance apparatus to assist in the changing of states of bitcells of said portion of said nonvolatile memory to change bits of said data of said sensitive information to prevent recovery of at least a portion of said sensitive information.

In Example 5, the subject matter of Examples 1-8 (excluding the present Example) can optionally include that said on-board erasure assistance apparatus is an electro-magnet positioned adjacent to said portion of said nonvolatile memory to direct a magnetic field through bitcells of said portion of said nonvolatile memory when activated, the controller configured to direct current through the electro-magnet to activate the electro-magnet to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

In Example 6, the subject matter of Examples 1-8 (excluding the present Example) can optionally include that said nonvolatile memory is a magnetoresistive Random Access Memory (MRAM).

In Example 7, the subject matter of Examples 1-8 (excluding the present Example) can optionally include that said MRAM is a Spin Transfer Torque Random Access Memory (STTRAM).

In Example 8, the subject matter of Examples 1-8 (excluding the present Example) can optionally include that said controller includes random bit selection logic configured to randomly select bitcells of said portion of said nonvolatile memory, said controller configured to direct write current to said randomly selected bitcells, and use said write current to change bits of said randomly selecting bitcells of said portion of said nonvolatile memory to prevent recovery of at least a portion of said sensitive information.

Example 9 is a computing system for use with a display, comprising:

a memory configured to store sensitive information in at least a portion of the memory;

a processor configured to write data in and read data from the memory;

a video controller configured to display information represented by data in the memory;

a detector configured to detect a security event; and

a controller coupled to the detector, processor and memory, said controller configured to protect sensitive information stored as data in the at least a portion of the memory, including said controller configured to, in response to said detector detecting a first security event, change bits of said data of said sensitive information to prevent recovery of at least a portion of said sensitive information by reading said portion of said memory.

In Example 10, the subject matter of Examples 9-15 (excluding the present Example) can optionally include that said detector is configured to detect as a security event, initiation of one of power up and power down conditions of the apparatus.

In Example 11, the subject matter of Examples 9-15 (excluding the present Example) can optionally include that said memory is nonvolatile and said controller is configured to direct write current to said nonvolatile memory to change bits of said data of said sensitive information to prevent recovery of at least a portion of said sensitive information.

In Example 12, the subject matter of Examples 9-15 (excluding the present Example) can optionally include that said memory is nonvolatile, said apparatus further comprising an on-board erasure assistance apparatus coupled to said controller, said controller configured activate the on-board erasure assistance apparatus to assist in the changing of states of bitcells of said portion of said nonvolatile memory to change bits of said data of said sensitive information to prevent recovery of at least a portion of said sensitive information.

In Example 13, the subject matter of Examples 9-15 (excluding the present Example) can optionally include that said on-board erasure assistance apparatus is an electro-magnet positioned adjacent to said portion of said nonvolatile memory to direct a magnetic field through bitcells of said portion of said nonvolatile memory when activated, the controller configured to direct current through the electro-magnet to activate the electro-magnet to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

In Example 14, the subject matter of Examples 9-15 (excluding the present Example) can optionally include that said nonvolatile memory is a magnetoresistive Random Access Memory (MRAM).

In Example 15, the subject matter of Examples 9-15 (excluding the present Example) can optionally include that said MRAM is a Spin Transfer Torque Random Access Memory (STTRAM).

In Example 16, the subject matter of Examples 9-15 (excluding the present Example) can optionally include that said controller includes random bit selection logic configured to randomly select bitcells of said portion of said nonvolatile memory, said controller configured to direct write current to said randomly selected bitcells, and use said write current to change bits of said randomly selecting bitcells of said portion of said nonvolatile memory to prevent recovery of at least a portion of said sensitive information.

Example 17 is a method, comprising:

protecting sensitive information stored as data in at least a portion of a memory of a device, said protecting including:

detecting a first event; and

in response to said first event detecting, changing bits of said data of said sensitive information to prevent recovery of at least a portion of said sensitive information by reading said portion of said memory.

In Example 18, the subject matter of Examples 17-24 (excluding the present Example) can optionally include that said detecting a first event includes detecting initiation of one of power up and power down conditions of the device.

In Example 19, the subject matter of Examples 17-24 (excluding the present Example) can optionally include that said memory is a nonvolatile memory and said changing bits of said data includes directing write current to said nonvolatile memory, and using said write current to change bits of said data of said sensitive information to prevent recovery of at least a portion of said sensitive information.

In Example 20, the subject matter of Examples 17-24 (excluding the present Example) can optionally include that said memory is a nonvolatile memory and said changing bits of said data includes activating an on-board erasure assistance device to assist in the changing of states of bitcells of said portion of said nonvolatile memory to change bits of said data of said sensitive information to prevent recovery of at least a portion of said sensitive information.

In Example 21, the subject matter of Examples 17-24 (excluding the present Example) can optionally include that said changing bits of said data includes directing current through an electro-magnet positioned adjacent said portion of said nonvolatile memory to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

In Example 22, the subject matter of Examples 17-24 (excluding the present Example) can optionally include that said nonvolatile memory is a magnetoresistive Random Access Memory (MRAM).

In Example 23, the subject matter of Examples 17-24 (excluding the present Example) can optionally include that said MRAM is a Spin Transfer Torque Random Access Memory (STTRAM).

In Example 24, the subject matter of Examples 17-24 (excluding the present Example) can optionally include that said changing bits of said data includes randomly selecting bitcells of said portion of said nonvolatile memory to be changed and directing write current to said randomly selected bitcells, and using said write current to change bits of said randomly selecting bitcells of said portion of said nonvolatile memory to prevent recovery of at least a portion of said sensitive information.

Example 25 is directed to an apparatus comprising means to perform a method as described in any preceding Example.

The described operations may be implemented as a method, apparatus or computer program product using standard programming and/or engineering techniques to produce software, firmware, hardware, or any combination thereof The described operations may be implemented as computer program code maintained in a “computer readable storage medium”, where a processor may read and execute the code from the computer storage readable medium. The computer readable storage medium includes at least one of electronic circuitry, storage materials, inorganic materials, organic materials, biological materials, a casing, a housing, a coating, and hardware. A computer readable storage medium may comprise, but is not limited to, a magnetic storage medium (e.g., hard disk drives, floppy disks, tape, etc.), optical storage (CD-ROMs, DVDs, optical disks, etc.), volatile and nonvolatile memory devices (e.g., EEPROMs, ROMs, PROMs, RAMs, DRAMs, SRAMs, Flash Memory, firmware, programmable logic, etc.), Solid State Devices (SSD), etc. The code implementing the described operations may further be implemented in hardware logic implemented in a hardware device (e.g., an integrated circuit chip, Programmable Gate Array (PGA), Application Specific Integrated Circuit (ASIC), etc.). Still further, the code implementing the described operations may be implemented in “transmission signals”, where transmission signals may propagate through space or through a transmission media, such as an optical fiber, copper wire, etc. The transmission signals in which the code or logic is encoded may further comprise a wireless signal, satellite transmission, radio waves, infrared signals, Bluetooth, etc. The program code embedded on a computer readable storage medium may be transmitted as transmission signals from a transmitting station or computer to a receiving station or computer. A computer readable storage medium is not comprised solely of transmissions signals. Those skilled in the art will recognize that many modifications may be made to this configuration without departing from the scope of the present description, and that the article of manufacture may comprise suitable information bearing medium known in the art. Of course, those skilled in the art will recognize that many modifications may be made to this configuration without departing from the scope of the present description, and that the article of manufacture may comprise any tangible information bearing medium known in the art.

In certain applications, a device in accordance with the present description, may be embodied in a computer system including a video controller to render information to display on a monitor or other display coupled to the computer system, a device driver and a network controller, such as a computer system comprising a desktop, workstation, server, mainframe, laptop, handheld computer, etc. Alternatively, the device embodiments may be embodied in a computing device that does not include, for example, a video controller, such as a switch, router, etc., or does not include a network controller, for example.

The illustrated logic of figures may show certain events occurring in a certain order. In alternative embodiments, certain operations may be performed in a different order, modified or removed. Moreover, operations may be added to the above described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to limit to the precise form disclosed. Many modifications and variations are possible in light of the above teaching.

What is claimed is:

1. An apparatus, comprising:
a memory configured to store sensitive information in at least a portion of the memory;
a detector configured to detect a security event; and
a controller coupled to the detector and memory, said controller configured to protect sensitive information stored as data in the at least a portion of the memory, including said controller configured to, in response to said detector detecting a first security event, change bits of said data of said sensitive information to prevent recovery of at least a portion of said sensitive information by reading said portion of said memory.

2. The apparatus of claim 1 wherein said detector is configured to detect as a security event, initiation of one of power up and power down conditions of the apparatus.

3. The apparatus of claim 1 wherein said memory is nonvolatile and said controller is configured to direct write current to said nonvolatile memory to change bits of said data of said sensitive information to prevent recovery of at least a portion of said sensitive information.

4. The apparatus of claim 1 wherein said memory is nonvolatile, said apparatus further comprising an on-board erasure assistance apparatus coupled to said controller, said controller configured activate the on-board erasure assistance apparatus to assist in the changing of states of bitcells of said portion of said nonvolatile memory to change bits of said data of said sensitive information to prevent recovery of at least a portion of said sensitive information.

5. The apparatus of claim 4 wherein said on-board erasure assistance apparatus is an electro-magnet positioned adjacent to said portion of said nonvolatile memory to direct a magnetic field through bitcells of said portion of said nonvolatile memory when activated, the controller configured to direct current through the electro-magnet to activate the electro-magnet to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

6. The apparatus of claim 5 wherein said nonvolatile memory is a magnetoresistive Random Access Memory (MRAM).

7. The apparatus of claim 6 wherein said MRAM is a Spin Transfer Torque Random Access Memory (STTRAM).

8. The apparatus of claim 3 wherein said controller includes random bit selection logic configured to randomly select bitcells of said portion of said nonvolatile memory, said controller configured to direct write current to said randomly selected bitcells, and use said write current to change bits of said randomly selecting bitcells of said portion of said nonvolatile memory to prevent recovery of at least a portion of said sensitive information.

9. A computing system for use with a display, comprising:
a memory configured to store sensitive information in at least a portion of the memory;
a processor configured to write data in and read data from the memory;
a video controller configured to display information represented by data in the memory;
a detector configured to detect a security event; and
a controller coupled to the detector, processor and memory, said controller configured to protect sensitive information stored as data in the at least a portion of the memory, including said controller configured to, in response to said detector detecting a first security event, change bits of said data of said sensitive information to prevent recovery of at least a portion of said sensitive information by reading said portion of said memory.

10. The system of claim 9 wherein said detector is configured to detect as a security event, initiation of one of power up and power down conditions of the apparatus.

11. The system of claim 9 wherein said memory is nonvolatile and said controller is configured to direct write current to said nonvolatile memory to change bits of said data of said sensitive information to prevent recovery of at least a portion of said sensitive information.

12. The system of claim 9 wherein said memory is nonvolatile, said apparatus further comprising an on-board erasure assistance apparatus coupled to said controller, said controller configured activate the on-board erasure assistance apparatus to assist in the changing of states of bitcells of said portion of said nonvolatile memory to change bits of said data of said sensitive information to prevent recovery of at least a portion of said sensitive information.

13. The system of claim 12 wherein said on-board erasure assistance apparatus is an electro-magnet positioned adjacent to said portion of said nonvolatile memory to direct a magnetic field through bitcells of said portion of said nonvolatile memory when activated, the controller configured to direct current through the electro-magnet to activate the electro-magnet to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

14. The system of claim 13 wherein said nonvolatile memory is a magnetoresistive Random Access Memory (MRAM).

15. The system of claim 14 wherein said MRAM is a Spin Transfer Torque Random Access Memory (STTRAM).

16. The system of claim 11 wherein said controller includes random bit selection logic configured to randomly select bitcells of said portion of said nonvolatile memory, said controller configured to direct write current to said randomly selected bitcells, and use said write current to change bits of said randomly selecting bitcells of said portion of said nonvolatile memory to prevent recovery of at least a portion of said sensitive information.

17. A method, comprising:
protecting sensitive information stored as data in at least a portion of a memory of a device, said protecting including:
detecting a first event; and
in response to said first event detecting, changing bits of said data of said sensitive information to prevent recovery of at least a portion of said sensitive information by reading said portion of said memory.

18. The method of claim 17 wherein said detecting a first event includes detecting initiation of one of power up and power down conditions of the device.

19. The method of claim 17 wherein said memory is a nonvolatile memory and said changing bits of said data includes directing write current to said nonvolatile memory, and using said write current to change bits of said data of said sensitive information to prevent recovery of at least a portion of said sensitive information.

20. The method of claim 17 wherein said memory is a nonvolatile memory and said changing bits of said data includes activating an on-board erasure assistance device to assist in the changing of states of bitcells of said portion of said nonvolatile memory to change bits of said data of said sensitive information to prevent recovery of at least a portion of said sensitive information.

21. The method of claim 19 wherein said changing bits of said data includes directing current through an electro-magnet positioned adjacent said portion of said nonvolatile memory to direct a magnetic field through bitcells of said portion of said nonvolatile memory to assist in the changing of states of bitcells of said portion of said nonvolatile memory to change bits of said data of said sensitive information to prevent recovery of at least a portion of said sensitive information.

22. The method of claim 21 wherein said nonvolatile memory is a magnetoresistive Random Access Memory (MRAM).

23. The method of claim 22 wherein said MRAM is a Spin Transfer Torque Random Access Memory (STTRAM).

24. The method of claim 19 wherein said changing bits of said data includes randomly selecting bitcells of said portion of said nonvolatile memory to be changed and directing write current to said randomly selected bitcells, and using said write current to change bits of said randomly selecting bitcells of said portion of said nonvolatile memory to prevent recovery of at least a portion of said sensitive information.
